(19) United States
(12) Patent Application Publication
(10) Pub. No.: US 2009/0014764 A1
(43) Pub. Date: Jan. 15, 2009

(54) IMAGE SENSOR WITH AN IMPROVED SENSITIVITY

(75) Inventors: Perceval COUDRAIN, Grenoble (FR); Philippe CORONEL, Barraux (FR); Xavier BELREDON, Eguilles (FR)

Correspondence Address: GRAYBEAL JACKSON LLP, 155 - 108TH AVENUE NE, SUITE 350, BELLEVUE, WA, 98004-5973, US

(73) Assignees: STMICROELECTRONICS SA, Montrouge (FR); STMICROELECTRONICS CROLLES 2 SAS, Crolles (FR)

(21) Appl. No.: 12/171,213

(22) Filed: Jul. 10, 2008

(30) Foreign Application Priority Data
Jul. 12, 2007 (FR) 0756447

(51) Int. Cl. H01L 31/00; H01L 21/00

(52) U.S. Cl. 257/294; 257/432; 438/93; 257/E31.001; 257/E21.001

(57) ABSTRACT

An embodiment of an image sensor comprising photosensitive cells, each photosensitive cell comprising at least one charge storage means formed at least partly in a substrate of a semiconductor material. The substrate comprises, for at least one first photosensitive cell, a portion of a first silicon and germanium alloy having a first germanium concentration, possibly zero, and for at least one second photosensitive cell, a portion of a second silicon and germanium alloy having a second germanium concentration, non-zero, greater than the first germanium concentration.

### PRIORITY CLAIM

This application claims priority from French patent application No. 07/56447, filed Jul. 12, 2007, which is incorporated herein by reference.

### BACKGROUND

1. Technical Field

An embodiment of the present invention relates to an image sensor made in monolithic form and intended to be used in shooting devices such as for example cameras, camcorders, digital microscopes, digital photographic devices, or endoscopes. More specifically, an embodiment of the present invention relates to a semiconductor-based image sensor.

2. Discussion of the Related Art

There are two large families of image sensors. Image sensors made according to the CCD technology (CCD standing for Charge-Coupled Device) and image sensors made according to the CMOS technology (CMOS standing for Complementary Metal Oxide Semiconductor). In all cases, the light is converted in a layer of a semiconductor material, for example, silicon, into exploitable electric signals.

Conventionally, an image sensor made in monolithic form comprises photosensitive cells, or pixels, each comprising charge storage means formed in a single-crystal silicon substrate, the storage means generally corresponding to a photodiode for a CMOS transistor and to a MOS capacitance for a CCD sensor. A stacking of insulating and conductive layers covers the substrate, and metal tracks and vias are formed in these layers to connect the storage means to other components. Microlenses are distributed on the upper surface of the stacking of insulating and conductive layers, each lens being associated with a pixel and focusing the light rays reaching the upper surface of the image sensor towards the storage means of the associated pixel. In the case of a color image sensor, color filters may be added under the focusing microlenses. Such an image sensor structure is called a front-lit image sensor.

According to another conventional image sensor example, the charge storage means are formed in a substrate corresponding to a thin single-crystal silicon layer which is lit on its rear surface. The sensor thus formed is called a back-lit image sensor. An advantage of a back-lit image sensor over a front-lit image sensor is that the focusing of the light rays towards the storage means of the pixels is eased since the light rays do not have to cross the stacking of insulating and conductive layers.

When the image sensor is lit, the incident photons are absorbed in the silicon substrate and cause the forming of electron/hole pairs, the electrons being captured by the storage means of the pixels. Generally, the silicon substrate thickness necessary for a majority of the photons of a given wavelength to be absorbed increases along with the wavelength. To ensure the absorption of a sufficient amount of photons of large wavelengths of the visible spectrum (mainly corresponding to red), it is generally necessary for the silicon substrate thickness to be greater than 3 μm. However, even with such thicknesses, it is possible for the absorption rate of photons of large wavelengths not to be maximum so that the image sensor sensitivity is different according to the wavelength of the incident photons. It may then be necessary to provide a compensation processing of the signals provided by the image sensor to take into account this non-uniform sensitivity.

The electrons resulting from the absorption of photons focused by a microlens are captured by the associated storage means. However, it may be observed that some electrons resulting from the absorption of photons are not captured by the storage means for which they are intended, but by neighboring storage means. This translates as a disturbance in the amount of charges stored by the storage means and thus as a disturbance of the signals provided by the sensor. This phenomenon is called “crosstalk” and is all the stronger as the electron-forming location is remote from the photodiodes.

For a front-lit image sensor, the crosstalk mainly concerns the photons of the visible spectrum of large wavelengths (mainly corresponding to color red) which may cause the forming of electrons distant by several micrometers from the storage means. For a back-lit image sensor, the crosstalk is particularly significant for photons of small wavelengths (mainly corresponding to colors blue and green) for which most of the electrons form down to a small substrate depth, smaller than one micrometer, from the rear surface of the sensor, that is, on the substrate side opposite to the storage means. Indeed, for such wavelengths, the distance that the electrons must cover to reach the storage means for which they are intended is typically greater than one micrometer and the risk for electrons to move towards other more distant storage means is not negligible.

It may be devised, to decrease crosstalk phenomena, to decrease the substrate thickness, which would bring the storage means closer to the electron/hole pair forming areas. However, this may not be envisaged since the image sensor sensitivity might then be too strongly altered for large wavelengths.

Another possibility would be to form, across the entire substrate thickness, insulation areas separating the pixels and for example corresponding to regions of an insulating material or to heavily-doped regions. It is however difficult to form insulation areas which are both deep and narrow on a substrate with a thickness of several micrometers, without greatly increasing the total sensor surface area.

### SUMMARY

An embodiment of the present invention aims at providing an image sensor enabling decreasing the crosstalk phenomenon between adjacent pixels while improving the sensor sensitivity.

Thus, an embodiment of the present invention provides an image sensor comprising photosensitive cells, each photosensitive cell comprising at least one charge storage means formed at least partly in a substrate of a semiconductor material. The substrate comprises, for at least one first photosensitive cell, a portion of a first silicon and germanium alloy having a first germanium concentration, possibly zero, and for at least one second photosensitive cell, a portion of a second silicon and germanium alloy having a second germanium concentration, non-zero, greater than the first germanium concentration.

According to an embodiment, the substrate comprises, for at least one third photosensitive cell, a portion of a third silicon and germanium alloy having a third germanium concentration, non-zero, greater than the second germanium concentration.

According to an embodiment, the substrate has a thickness smaller than 1 micrometer, for example, smaller than 500 nanometers.

According to an embodiment, the substrate comprises, at least for the second photosensitive cell, a single-crystal silicon portion adjacent to the second silicon and germanium alloy portion, the single-crystal silicon portion containing the charge storage means associated with the second photosensitive cell.

According to an embodiment, the image sensor comprises an insulation area separating the first and second photosensitive cells and extending across the entire thickness of the substrate.

According to an embodiment, the first photosensitive cell comprises a first filter capable of letting through light rays having first wavelengths and the second photosensitive cell comprises a second filter capable of letting through light rays having second wavelengths greater than the first wavelengths.

An embodiment of the present invention provides a method for manufacturing an image sensor comprising photosensitive cells, comprising the steps of:

(a) providing a single-crystal silicon layer;

(b) forming, at least partly in the layer, for at least one first photosensitive cell, a portion of a first silicon and germanium alloy having a first germanium concentration, possibly zero, and, for at least one second photosensitive cell, a portion of a second silicon and germanium alloy having a second non-zero germanium concentration, greater than the first germanium concentration; and

(c) forming, for each photosensitive cell, a charge storage means at least partly in the layer.

According to an embodiment, step (b) comprises at least one step of germanium ion implantation in the layer.

According to an embodiment, step (b) comprises the steps of forming on the layer, at least at the level of the second photosensitive cell, a portion of a fourth silicon and germanium alloy; and growing, by thermal oxidation, a silicon oxide portion which extends into the portion of the fourth silicon and germanium alloy, which results in the migration of the germanium into said layer to form the second silicon and germanium alloy portion.

According to an embodiment, step (b) comprises the steps of forming on the layer, at least at the level of the second photosensitive cell, a portion of a fifth silicon and germanium alloy; insulating the second photosensitive cell with areas of an insulating material; and melting, at least partially, the fifth silicon and germanium alloy portion, which results, by interdiffusion, in the forming of the second silicon and germanium alloy portion.

The foregoing and other features and advantages of one or more embodiments of the present invention will be discussed in detail in the following non-limiting description in connection with the accompanying drawings.

### BRIEF DESCRIPTION OF THE DRAWINGS

FIG. 1 shows an embodiment of a back-lit image sensor according to the present invention;

FIG. 2 shows another embodiment of a back-lit image sensor according to the present invention;

FIGS. 3A to 3E show structures obtained after steps of an example of a method for manufacturing the sensor of FIG. 1;

FIGS. 4A to 4C show structures obtained after steps of an example of a method for manufacturing a variation of the image sensor of FIG. 1; and

FIGS. 5A to 5D show structures obtained after steps of another example of a method for manufacturing the image sensor of FIG. 2.

### DETAILED DESCRIPTION

For clarity, the same elements have been designated with the same reference numerals in the different drawings and, further, as usual in the representation of integrated circuits, the various drawings are not to scale. In the following description, color image sensors comprising three types of pixels respectively associated with colors blue, green, and red will be considered.

To limit the crosstalk phenomenon in an image sensor, it is provided to decrease the substrate thickness so that the electron generation occurs as close as possible to the charge storage means. This further eases the forming of insulation areas separating the pixels and extending across the entire substrate thickness. However, to avoid altering the sensor sensitivity, in particular to large wavelengths, it is provided, at least for the pixels associated with photons of large wavelengths, that is, the red pixels in the present example, to form the substrate portion associated with the pixel with a material different from single-crystal silicon, thus enabling more efficient absorption of photons of large wavelengths. An additional constraint is that the used material is compatible with conventional CMOS and CCD sensor manufacturing processes. By many tests, it has been shown that a silicon and germanium alloy fulfills such requirements. Indeed, the greater the germanium concentration in a silicon-germanium alloy, the more the capacity to absorb photons of large wavelengths in the visible spectrum increases.

An embodiment of the present invention will now be described for a CMOS image sensor. It should however be clear that an embodiment of the present invention also applies to a CCD image sensor. Further, in the following description, a back-lit image sensor is considered. It should however be clear that an embodiment of the present invention also applies to a front-lit image sensor.

FIG. 1 shows of a CMOS image sensor 1 according to an embodiment of the present invention. Three pixels B, G, R are shown and are associated, for example, respectively with colors blue, green, and red. In the following description, suffixes B, G, or R are associated with certain reference numerals to more specifically designate an element belonging to pixel B, G, or R.

An element forming a support 5, for example, a semiconductor wafer, is covered with a stacking of insulating and conductive layers 7 and with a substrate 9. Substrate 9 is formed of adjacent portions of lightly P-type doped silicon-germanium alloys 10B, 10G, 10R (P³¹). Respectively call X_{B}, X_{G}, and X_{R} are the germanium concentrations in the silicon-germanium alloy of portions 10B, 10G, and 10R. The germanium concentration is substantially uniform across each portion 10B, 10G, and 10R. The thickness of substrate 9, which is substantially constant, is designated with reference τ_{f}. As an example, thickness τ_{f} is smaller than or equal to 1 μm, for example, smaller than or equal to 500 nm. Photodiodes 11B, 11G, 11R (not shown in detail) and MOS transistor source and drain regions (not shown) are formed in substrate 9 on the side of stacking 7. The insulation between adjacent pixels is provided by P-type areas 16 which are more heavily doped (P⁺) than portions 10B, 10G, and 10R and which extend across the entire thickness of substrate 9. The transistor gates are formed at the surface of substrate 9 on the side of stacking 7. Metal tracks and vias enabling connection between the different system components (photodiodes, transistors . . . ) are formed in stacking 7. On the surface of substrate 9 opposite to stacking 7 are formed, at the level of each pixel B, G, and R, color filters 17B, 17G, and 17R and microlenses 19B, 19G, 19R enabling focusing the light rays towards photodiodes 11B, 11G, and 11R. Color filter 17B, associated with pixel B, lets through, in the visible spectrum, the light rays having wavelengths close to color blue, color filter 17G, associated with pixel G, lets through, in the visible spectrum, the light rays having wavelengths close to color green, and color filter 17R, associated with pixel R, lets through, in the visible spectrum, the light rays having wavelengths close to color red.

When image sensor 1 is illuminated, the incident photons are absorbed in substrate 9 by causing the forming of electron/hole pairs, the electrons being captured by photodiodes 11B, 11G, and 11R of pixels B, G, and R.

Absorption rate A of photons in each portion 10B, 10G, and 10R of substrate 9 is provided by the following relation:

$$A = 1 \text{-} {e}^{\frac{- 4 π k}{λ} {τ}_{f}} \qquad ( 1 )$$

where k is the extinction coefficient of the material forming the considered portion 10B, 10G, or 10R of substrate 9 and λ is the wavelength of the incident photons.

Concentrations X_{B}, X_{G}, and X_{R} are selected so that, for a same thickness τ_{f} of substrate 9, the absorption rates of portions 10B, 10G, and 10R of pixels B, G, and R are substantially sufficient for the wavelengths of the light rays associated with these pixels. For example, the absorption rates of portions 10B, 10G, and 10R are maximum and identical. For this purpose in this example, concentration X_{R} is greater than concentration X_{G} which is itself greater than concentration X_{B}. As an example, for a concentration X_{B} equal to 0%, concentration X_{G} may be on the order of 15% and concentration X_{R} may be on the order of 30%. The general sensitivity of the image sensor may thus be substantially uniform for all wavelengths in the visible spectrum. Further, since thickness τ_{f} may be smaller than 1 μm, the electron generation location is close to the photodiodes, which enables decreasing the crosstalk. Further, insulation areas 16 may easily be formed across the entire thickness τ_{f} of substrate 9. This enables further limiting the crosstalk.

FIG. 2 shows another embodiment of an image sensor 20 according to the present invention. As compared with image sensor 1 shown in FIG. 1, sensor 20 comprises a single-crystal silicon portion 24B, 24G, and 24R, for each pixel B, G, and R, at the level of the corresponding photodiode 11B, 11G, 11R. Each single-crystal silicon portion 24B, 24G, and 24R is thus interposed between the corresponding silicon-germanium portion 10B, 10G, and 10R and the stacking of insulating and conductive layers 7. Since the determination of the properties of photodiodes 11B, 11G, 11R and of the channel regions of the MOS transistors (not shown) associated with each pixel B, G, and R is relatively complex and is well controlled for conventional image sensors in which the substrate is made of single-crystal silicon, single-crystal silicon portions 24B, 24G, and 24R enable using structures of photodiodes 11B, 11G, and 11R and of MOS transistors already defined for conventional image sensors with a single-crystal silicon substrate. Sensor 20 however, may benefit from the improvement in sensitivity and from the reduction of crosstalk phenomena due to the presence of silicon-germanium portions 10B, 10G, and 10R at the level of each pixel B, G, and R.

For the image sensor shown in FIG. 2, for each pixel B, G, and R, the curvature of the energy bands at the interface between silicon-germanium portion 10B, 10G, and 10R and the adjacent silicon portion 24B, 24G, and 24R may cause the forming of an oriented electric field substantially perpendicular to the rear surface of the sensor and which tends to direct the electrons photogenerated in silicon-germanium portions 10B, 10G, and 10R towards the corresponding photodiode 11B, 11G, 11R. The presence of this electric field takes part in the crosstalk reduction and enables, if desirable, keeping the thicknesses of silicon-germanium portions 10B, 10G, and 10R greater than one micrometer, for example, on the order of 3 μm.

According to a variation of the previously described embodiments, silicon-germanium portions 10R, 10G are provided only at the level of each red and green pixel, the substrate portion associated with each blue pixel corresponding to single-crystal silicon. Since most of the photons corresponding to color blue are absorbed in a thickness on the order of 500 nm in the case of a single-crystal silicon substrate, a reduced thickness may be maintained for substrate 9.

According to another variation of the previously described embodiments, a portion only of silicon-germanium 10R is provided at the level of each red pixel, the substrate portions associated with each blue and green pixel corresponding to single-crystal silicon. Since most of the photons corresponding to color green are absorbed in a thickness on the order of 1 μm in the case of a single-crystal silicon substrate, a reduced thickness may be maintained for substrate 9.

According to another variation of the previously described embodiments, insulation areas 16 may correspond to regions of an insulating material, for example, silicon oxide, and may be formed by a method of shallow trench insulation type (STI).

According to another variation of the previously-described embodiments, for each pixel B, G, and R, a P-type dopant concentration gradient may be provided in silicon-germanium portions 10B, 10G, and 10R according to the stacking direction of sensor layers, that is, the dopant concentration decreases from the rear surface of the sensor. Such a gradient causes, for each pixel R, G, and B, the forming of an electric field in silicon-germanium portion 10B, 10G, and 10R oriented substantially perpendicularly to the rear sensor surface and which tends to direct the electrons photogenerated in the silicon-germanium portion 10B, 10G, and 10R towards the corresponding photodiode 11B, 11G, 11R.

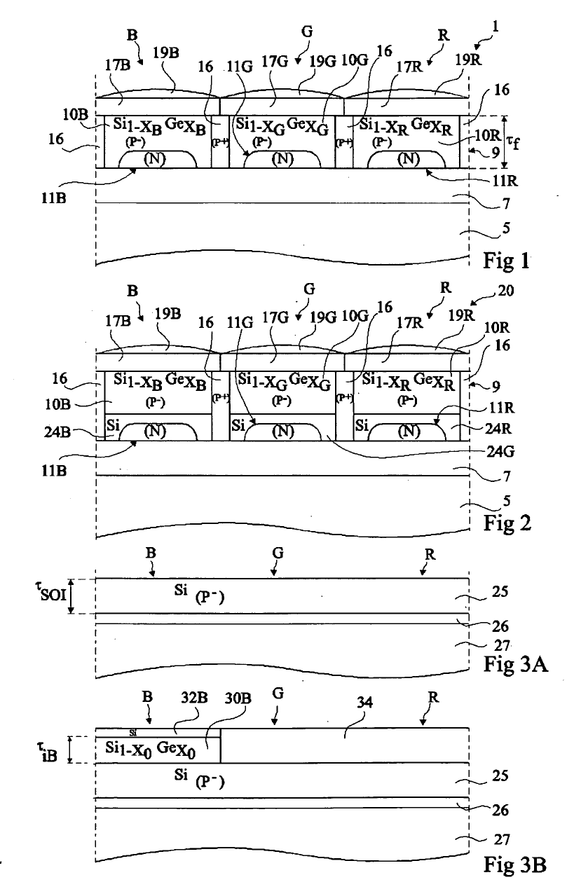

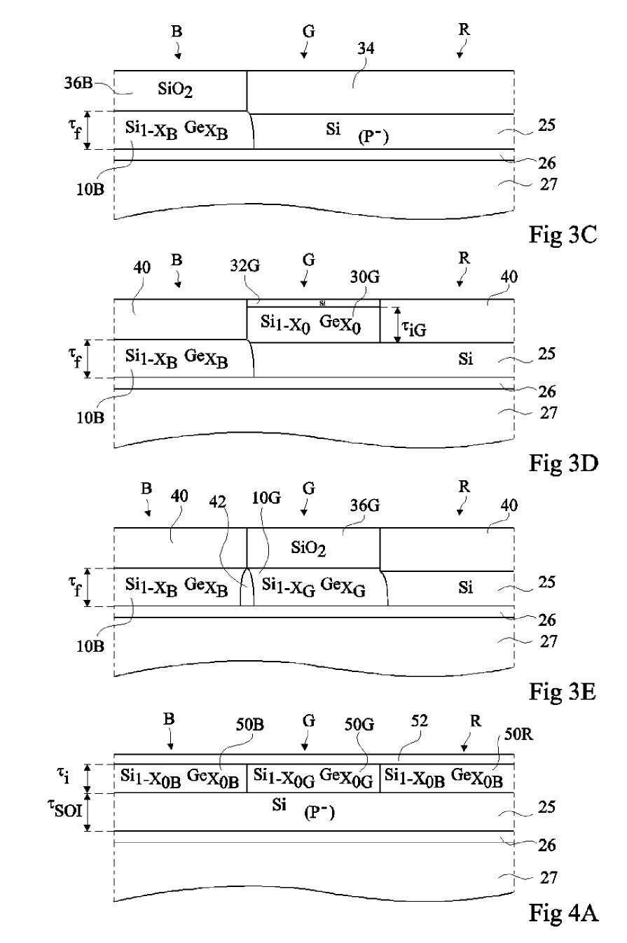

An example of a method for manufacturing the image sensor of FIG. 1 or 2 will now be described in relation with FIGS. 3A to 3E.

FIG. 3A shows a structure of substrate on insulator or SOI type comprising the stacking of a single-crystal silicon layer 25, for example, lightly P-type doped, of an insulating layer 26, for example, silicon oxide, and of a support 27, for example, a silicon wafer. Silicon layer 25 for example has a dopant concentration of 10¹⁵ atoms/cm³. The thickness of layer 25 is designated with reference τ_{SOI}.

FIG. 3B shows the structure obtained after having formed on silicon layer 25, at the level of each blue pixel B, a portion of a silicon-germanium alloy 30B having a thickness τ_{iB} and having a germanium concentration X₀. Portion 30B is covered with a single-crystal silicon portion 32B and the rest of the sensor is covered with a protection portion 34, for example, a silicon nitride layer or a silicon oxide layer. More specifically, the forming of portions 30B, 32B, and 34 may comprise the steps of:

forming over the entire layer 25 a layer of the silicon-germanium alloy with concentration X₀ and thickness τ_{iB}, for example, by epitaxial growth under a gas flow, for example, of silane and germane;

forming a first mask on the silicon surface layer covering the silicon surface layer only at the level of the blue pixels;

anisotropically etching the portions of the silicon surface layer and of the silicon-germanium layer unprotected by the first mask to form silicon-germanium portion 30B and silicon portion 32B;

removing the first mask;

depositing a protection layer over the entire obtained structure;

forming a second mask which covers the protection layer only at the level of the green and red pixels;

anisotropically etching the portions of the protection layer unprotected by the second mask to expose silicon portion 32B at the level of each blue pixel and form protection layer 34; and

removing of the second mask.

FIG. 3C shows the structure obtained after having carried out a step of thermal oxidation of the structure of FIG. 3B. This step may be carried out by heating under an oxygen flow. The oxide propagates into silicon portion 32B, which turns this layer into a silicon oxide portion 36B. The oxidation is continued so that the oxide propagation edge penetrates into silicon-germanium portion 30B. The propagation of silicon oxide portion 36B causes the migration of the germanium atoms of silicon-germanium portion 30B towards the bottom of FIG. 3C, which leads portion 30B to extend downwards by transformation of a portion of silicon layer 25 into silicon-germanium. The oxidation operation is carried on until silicon-germanium portion 30B extends across the entire thickness of silicon layer 25 and forms silicon-germanium portion 10B having germanium concentration X_{B} and thickness τ_{f}. Thicknesses τ_{iB}, τ_{f} and concentrations X₀ and X_{B} are linked by the following relation:

X_{B}=X₀(τ_{iB}/τ_{f}) (2)

FIG. 3D shows the structure obtained after having formed on silicon layer 25, at the level of each green pixel, a portion of a silicon-germanium alloy 30G having a thickness τ_{iG} and having a germanium concentration X₀. Portion 30G is covered with a single-crystal silicon portion 32G and the rest of the sensor is covered with a protection portion 40, of example, a silicon nitride layer or a silicon oxide layer. More specifically, the forming of portions 30G, 32G, and 40 may comprise the steps of:

removing protection portion 34 and silicon oxide portion 36B;

forming over the entire layer 25 a layer of the silicon-germanium alloy with concentration X₀ and thickness τ_{iG}, for example, by epitaxial growth under a gas flow, for example, of silane and germane;

forming a single-crystal silicon surface layer on the silicon-germanium alloy;

forming a first mask on the silicon surface layer covering the silicon surface layer at the level of the green pixels only;

anisotropically etching the portions of the silicon surface layer and of the silicon-germanium layer unprotected by the first mask to form silicon-germanium layer 30G and silicon portion 32G;

removing the first mask;

depositing a protection layer over the entire obtained structure;

forming a second mask which covers the protection layer at the level of the blue and red pixels only;

anisotropically etching the portions of the protection layer unprotected by the second mask to expose silicon portion 32G at the level of each green pixel and form protection portion 40; and

removing the second mask.

FIG. 3E shows the structure obtained after having performed a step of thermal oxidation of the structure of FIG. 3D. The downward migration of the germanium in FIG. 3E is obtained, as described previously, by the growth of a silicon oxide portion 36G to form silicon-germanium portion 10G having germanium concentration X_{G}. Region 42 corresponds to a border area between portions 10B and 10G in which the germanium concentration varies.

The forming of silicon-germanium portion 10R at the level of each red pixel may be carried out by steps similar to what has been described previously for the forming of portion 10G. Heavily-doped P-type insulation areas 16 are finally formed to delimit the pixels.

The image sensor manufacturing method carries on with the steps of:

to obtain the structure shown in FIG. 2, forming a lightly-doped P-type single-crystal silicon layer (with, for example, a 10¹⁵ atom/cm³ dopant concentration), covering portions 10B, 10G, and 10R, and forming photodiodes 11B, 11G, and 11R and the MOS transistors at the level of this layer. To obtain the structure shown in FIG. 1, forming photodiodes 11B, 11G, and 11R and the MOS transistors at the level of silicon-germanium portions 10B, 10G, and 10R;

forming the stacking of insulating and conductive layers 7 on the obtained structure;

attaching support 5, for example, by gluing, to the stacking of insulating and conductive layers 7;

thinning down the structure by removal of support 27 and of insulating layer 26 to expose the rear sensor surface;

forming filters 17B, 17G, and 17R and microlenses 19B, 19G, and 19R on the rear surface side of the sensor.

To obtain a front-lit image sensor, the thinning step does not take place and filters 17B, 17G, and 17R and microlenses 19B, 19G, and 19R are formed on the stacking of insulating and conductive layers 7.

In the previously-described manufacturing method example, different germanium concentrations X_{B}, X_{G}, and X_{R} for silicon-germanium portions 10B, 10G, and 10R associated with the blue, green, and red pixels are obtained by providing different initial thicknesses τ_{iB}, τ_{iG}, and τ_{iR} for silicon-germanium portions 30B, 30G, and 30R for which the initial germanium concentration is X₀.

According to a variation of the previously-described manufacturing method, silicon-germanium portions 30B, 30G, and 30R are formed before the oxidation step, which then results in the simultaneous forming of silicon-germanium portions 10B, 10G, and 10R. Since portions 30B, 30G, and 30R then have the same thickness, different germanium concentrations X_{B}, X_{G}, and X_{R} for portions 10B, 10G, and 10R are obtained by providing different initial germanium concentrations for portions 30B, 30G, and 30R.

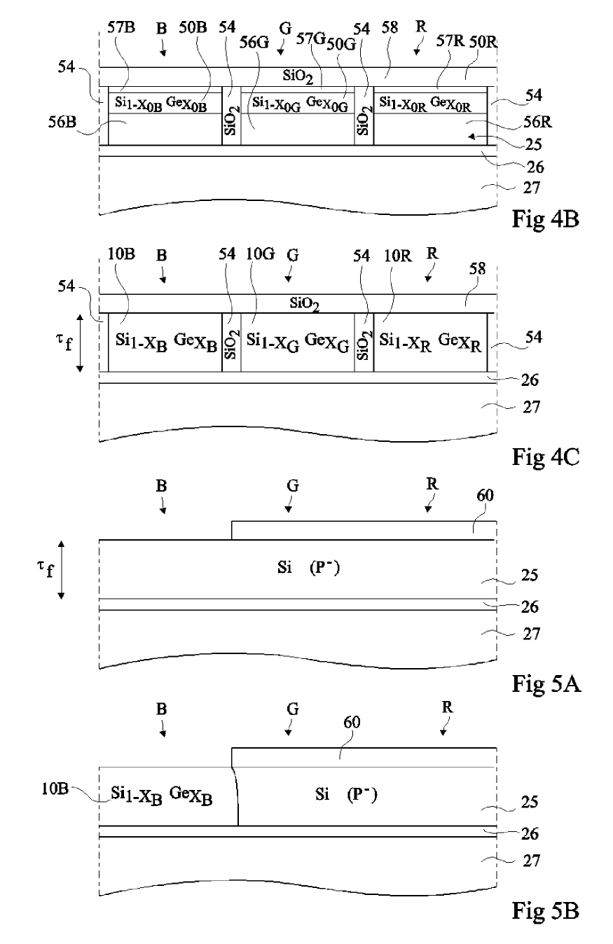

An example of a method for manufacturing a variation of the image sensor of FIG. 1 will now be described in relation with FIGS. 4A to 4C. In this image sensor variation, the insulation between silicon-germanium portions 10B, 10G, and 10R is performed by portions of an insulating material, for example, silicon oxide.

The initial structure corresponds to that shown in FIG. 3A.

FIG. 4A shows the structure obtained after having formed, on silicon layer 25, silicon-germanium portions 50B, 50G, 50R, respectively at the level of pixels B, G, and R, having the same thickness τᵢ and having different initial germanium concentrations, respectively X_{0B}, X_{0G}, and X_{0R}, and after having covered the obtained structure with a silicon layer 52. More specifically, the forming of portions 50B, 50G, and 50R and of layer 52 may comprise the steps of:

forming over the entire layer 25 a layer of the silicon-germanium alloy with concentration X_{0B} and thickness τᵢ, for example, by epitaxial growth under a gas flow, for example, of silane and germane;

forming a mask on the silicon-germanium layer covering the silicon layer at the level of the blue pixels only;

anisotropically etching the portions of the silicon-germanium layer unprotected by the mask to form silicon-germanium portion 50B;

removing the mask;

repeating the preceding steps to form silicon-germanium portions 50G and 50R; and

depositing silicon layer 52.

FIG. 4B shows the structure obtained after having formed insulation layers 54 separating the pixels and extending across the entire thickness of silicon layer 25, of silicon-germanium portions 50B, 50G, and 50R, and of silicon layer 52 and after having covered the obtained structure with a silicon oxide layer 58. Insulation areas 54 correspond to areas of an insulating material, for example, silicon oxide, and may be formed by an STI-type method (shallow trench insulation). Insulation areas 54 delimit, respectively at the level of blue, green, and red pixels B, G, and R, silicon portions 56B, 56G, and 56R in silicon layer 25 and delimit silicon portions 57B, 57G, and 57R in silicon layer 52.

FIG. 4C shows the structure obtained after having performed a high-temperature anneal, for example, on the order of 1,200° C. The heating operation results in an at least partial melting of silicon-germanium portions 50B, 50G, and 50R having a melting point lower than that of single-crystal silicon, which is on the order of 1,410° C. The absorption of the silicon in silicon portions 56B, 56G, and 56R and 57B, 57G, and 57R which passes through the melt is obtained by interdiffusion. After cooling, silicon-germanium portions 10B, 10G, and 10R of a thickness τ_{f} are obtained, which each extend on locations previously occupied by silicon portions 56B, 56G, and 56R, silicon-germanium portions 50B, 50G, and 50R, and silicon portions 57B, 57G, and 57R. The values of germanium concentrations X_{B}, X_{G}, and X_{R} of silicon-germanium portions 10B, 10G, and 10R may be obtained from relation (2). More specifically, taking into account the fact that thickness τ_{f} is substantially equal to the sum of the thicknesses τ_{SOI} and τᵢ (neglecting the thickness of silicon layer 52), expression (2) can be written, for example, for blue pixel B, as:

$${τ}_{i} = {τ}_{SOI} ( \frac{{X}_{B}}{{X}_{0 B} - {X}_{B}} ) \qquad ( 3 )$$

In this example of a manufacturing method, the different concentrations X_{B}, X_{G}, and X_{R} of silicon-germanium portions 10B, 10G, and 10R are obtained by varying initial concentrations X_{0B}, X_{0G}, and X_{0R}.

The next steps of the present example of a manufacturing method may be identical to what has been described for the example of a manufacturing method illustrated in FIGS. 3A to 3E.

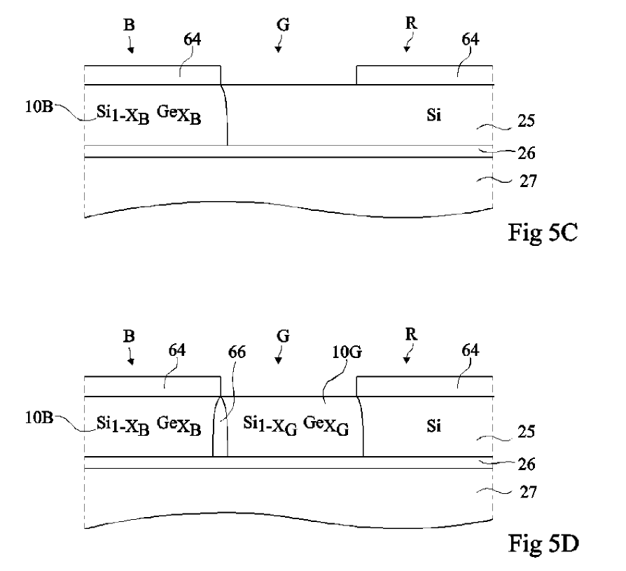

Another example of an image sensor manufacturing method of FIG. 1 will now be described in relation with FIGS. 5A to 5D.

The initial structure corresponds to a structure similar to that shown in FIG. 3A, thickness τ_{SOI} of silicon layer 25 corresponding in this case to the desired final thickness τ_{f} silicon-germanium portions 10B, 10G, and 10R.

FIG. 5A shows the structure obtained after having formed a mask 60 covering layer 25 at the level of green and red pixels G, R only.

FIG. 5B shows the structure obtained after having formed, at the level of each blue pixel B by implantation of germanium ions, silicon-germanium portion 10B in the portion of layer 25 unprotected by mask 60 and having a germanium concentration X_{B}. To obtain a substantially uniform distribution of the germanium in portion 10B, it may be necessary to provide several successive germanium implantation steps with different implantation energies.

FIG. 5C shows the structure obtained after having removed mask 60 and having formed on layer 25 a mask 64 which covers layer 25 at the level of blue and red pixels B, R only.

FIG. 5D shows the structure obtained after having formed in silicon layer 25, at the level of each green pixel, by ion germanium implantation, silicon-germanium portion 10G at the level of the portion of layer 25 unprotected by mask 64 and having a germanium concentration X_{G}. As described previously, portion 10G may be obtained by successive steps of implantation of germanium ions in silicon layer 25. Region 66 corresponds to an interface region between silicon-germanium portions 10B and 10G in which the germanium concentration varies.

The forming of silicon-germanium portion 10R associated with each red pixel R may be performed by steps similar to those previously described for the forming of portion 10G. A final step of forming of insulation areas 16 of the pixels, which may correspond to heavily-doped P-type regions, is provided.

The next steps of the present example of a manufacturing method may be identical to what has been described for the manufacturing method example illustrated in FIGS. 3A to 3E.

Specific embodiments of the present invention have been described. In particular, although the previously-described embodiments relate to color image sensors comprising pixels associated with colors blue, green, and red, it should be clear that an embodiment of the present invention may also apply to color sensors for which the pixels are associated with other colors, for example, the three primary colors (blue, yellow, red), the colors complementary to the primary colors (green, orange, purple), etc.

Such alterations, modifications, and improvements are intended to be part of this disclosure, and are intended to be within the spirit and the scope of the present invention. Accordingly, the foregoing description is by way of example only and is not intended to be limiting.

What is claimed:

1. An image sensor comprising photosensitive cells, each photosensitive cell comprising at least one charge storage means formed at least partly in a substrate of a semiconductor material, wherein the substrate comprises, for at least one first photosensitive cell, a portion of a first silicon and germanium alloy having a first germanium concentration, possibly zero, and for at least one second photosensitive cell, a portion (of a second silicon and germanium alloy having a second germanium concentration, non-zero, strictly greater than the first germanium concentration.

2. The image sensor of claim 1, wherein the substrate comprises, for at least one third photosensitive cell, a portion of a third silicon and germanium alloy having a third germanium concentration, non-zero, strictly greater than the second germanium concentration.

3. The image sensor of claim 1, wherein the substrate has a thickness smaller than 1 micrometer, preferably smaller than 500 nanometers.

4. The image sensor of claim 1, wherein the substrate comprises, at least for the second photosensitive cell, a single-crystal silicon portion adjacent to the second silicon and germanium alloy portion, the single-crystal silicon portion containing the charge storage means associated with the second photosensitive cell.

5. The image sensor of claim 1, comprising an insulation area separating the first and second photosensitive cells and extending across the entire thickness of the substrate.

6. The image sensor of claim 1, wherein the first photosensitive cell comprises a first filter capable of letting through light rays having first wavelengths and wherein the second photosensitive cell comprises a second filter capable of letting through light rays having second wavelengths greater than the first wavelengths.

7. A method for manufacturing an image sensor comprising photosensitive cells, comprising the steps of:
(a) providing a single-crystal silicon layer;
(b) forming, at least partly in said layer, for at least one first photosensitive cell, a portion of a first silicon and germanium alloy having a first germanium concentration, possibly zero, and, for at least one second photosensitive cell, a portion of a second silicon and germanium alloy having a second non-zero germanium concentration strictly greater than the first germanium concentration; and
(c) forming, for each photosensitive cell, a charge storage means at least partly in the layer.

8. The method of claim 7, wherein step (b) comprises at least one step of germanium ion implantation in the layer.

9. The method of claim 7, wherein step (b) comprises the steps of:
forming on the layer, at least at the level of the second photosensitive cell, a portion of a fourth silicon and germanium alloy; and
growing, by thermal oxidation, a silicon oxide portion which extends into the portion of the fourth silicon and germanium alloy, which results in the migration of the germanium into said layer to form the second silicon and germanium alloy portion.

10. The method of claim 7, wherein step (b) comprises the steps of:
forming on the layer, at least at the level of the second photosensitive cell, a portion of a fifth silicon and germanium alloy;
insulating the second photosensitive cell with areas of an insulating material; and
melting, at least partially, the fifth silicon and germanium alloy portion, which results, by interdiffusion, in the forming of the second silicon and germanium alloy portion.

11. An integrated circuit, comprising:
a substrate;
a layer disposed over the substrate and having a first region doped with a first concentration of germanium; and
a first photo detector having a first portion disposed in the substrate beneath the first region of the layer.

12. The integrated circuit of claim 11 wherein the substrate comprises silicon.

13. The integrated circuit of claim 11 wherein the layer comprises silicon.

14. The integrated circuit of claim 11 wherein the first photo detector comprises a CMOS photo detector.

15. The integrated circuit of claim 11, further comprising:
wherein the layer comprises a second region doped with a second concentration of germanium, the second concentration being different from the first concentration; and
a second photo detector having a first portion disposed in the substrate beneath the second region of the layer.

16. The integrated circuit of claim 11, further comprising:
wherein the layer comprises a second region doped with a second concentration of germanium, the second concentration being different from the first concentration;
a second photo detector having a first portion disposed in the substrate beneath the second region of the layer; and
wherein one of the first and second concentrations is substantially zero.

17. The integrated circuit of claim 11, further comprising:
wherein the layer comprises a second region doped with a second concentration of germanium, the second concentration being different from the first concentration;
a second photo detector having a first portion disposed in the substrate beneath the second region of the layer; and
wherein the first and second regions have substantially a same thickness.

18. The integrated circuit of claim 11, further comprising:
wherein the layer comprises a second region doped with a second concentration of germanium, the second concentration being different from the first concentration;
wherein the first concentration of germanium causes the first region of the layer to absorb light having a first wavelength;
wherein the second concentration of germanium causes the second region of the layer to absorb light having a second wavelength;
wherein the first photo detector is operable to sense a portion of the light absorbed by the first region of the layer; and
a second photo detector having a first portion disposed in the substrate beneath the second region of the layer and operable to sense a portion of the light absorbed by the second region of the layer.

19. The integrated circuit of claim 11 wherein:
the first wavelength is shorter than the second wavelength; and
the first concentration is smaller than the second concentration.

20. The integrated circuit of claim 11 wherein the light having the first wavelength and the light having the second wavelength are visible to the human eye.

21. The integrated circuit of 11 wherein:
the first wavelength comprises one of a red, a green, and a blue wavelength; and
the second wavelength comprises another of a red, a green, and a blue wavelength.

22. The integrated circuit of claim 11, further comprising:
wherein the layer comprises a second region doped with a second concentration of germanium, the second concentration being different from the first concentration;
wherein the first concentration of germanium causes the first region of the layer to generate electrons in response to light incident on the first region and having a first wavelength;
wherein the second concentration of germanium causes the second region of the layer to generate electrons in response to light incident on the second region and having a second wavelength;
wherein the first photo detector is operable to sense a portion of the electrons generated by the first region of the layer; and
a second photo detector having a first portion disposed in the substrate beneath the second region of the layer and operable to sense a portion of the electrons generated by the second region of the layer.

23. The integrated circuit of claim 11, further comprising:
wherein the layer comprises a second region doped with a second concentration of germanium, the second concentration being different from the first concentration;
wherein the first concentration of germanium causes the first region of the layer to absorb an amount of light having a first wavelength;
wherein the second concentration of germanium causes the second region of the layer to absorb an amount of light having a second wavelength;
wherein the first photo detector is operable to generate a first electrical signal having a parameter that is proportional to the amount of light absorbed by the first region of the layer; and
a second photo detector having a first portion disposed in the substrate beneath the second region of the layer and operable to generate a second electrical signal having a parameter that is proportional to the amount of light absorbed by the second region of the layer.

24. The integrated circuit of claim 11 wherein the layer has a second region disposed between the first region and the substrate and having a second concentration of germanium that is smaller than the first concentration.

25. The integrated circuit of claim 11 wherein the layer has a second region disposed between the first region and the substrate and including substantially no germanium.

26. The integrated circuit of claim 11 wherein the layer has a second region disposed between the first region and the substrate, including silicon, and including substantially no germanium.

27. The integrated circuit of claim 11 wherein:
the layer has a second region disposed between the first region and the substrate and having a second concentration of germanium that is smaller than the first concentration; and
the first photo detector has a second portion disposed in the second region of the layer.

28. The integrated circuit of claim 11 wherein the first photo detector has a second portion disposed in the first region of the layer.

29. The integrated circuit of claim 11, further comprising:
wherein the layer comprises a second region doped with a second concentration of germanium, the second concentration being different from the first concentration;
a second photo detector having a first portion disposed in the substrate beneath the second region of the layer; and
wherein the layer comprises an isolation region disposed between the first and second regions.

30. The integrated circuit of claim 11, further comprising:
wherein the layer comprises a second region doped with a second concentration of germanium, the second concentration being different from the first concentration;
a second photo detector having a first portion disposed in the substrate beneath the second region of the layer;
wherein the layer comprises a third region doped with a third concentration of germanium, the third concentration being different from the first and second concentrations; and
a third photo detector having a third portion disposed in the substrate beneath the third region of the layer.

31. The integrated circuit of claim 11, further comprising:
wherein the layer comprises a second region doped with a second concentration of germanium, the second concentration being different from the first concentration;
wherein the layer comprises a third region doped with a third concentration of germanium, the third concentration being different from the first and second concentrations;
wherein the first concentration of germanium causes the first region of the layer to absorb light having a first wavelength;
wherein the second concentration of germanium causes the second region of the layer to absorb light having a second wavelength;
wherein the third concentration of germanium causes the third region of the layer to absorb light having a third wavelength;
wherein the first photo detector is operable to sense a portion of the light absorbed by the first region of the layer;
a second photo detector having a first portion disposed in the substrate beneath the second region of the layer and operable to sense a portion of the light absorbed by the second region of the layer; and
a third photo detector having a first portion disposed in the substrate beneath the third region of the layer and operable to sense a portion of the light absorbed by the third region of the layer.

32. The integrated circuit of claim 11, further comprising a filter disposed over the first region of the layer and operable to substantially block wavelengths of light outside of a range of wavelengths.

33. The integrated circuit of claim 11, further comprising a lens disposed over the first region of the layer

34. A system, comprising:
an image sensor, including
a substrate,
a layer disposed over the substrate and having a first region doped with a first concentration of germanium, and
a first photo detector having a first portion disposed in the substrate beneath the first region of the layer; and
a controller coupled to the image sensor.

35. The system of claim 34, further comprising:
first and second integrated-circuit dies;
wherein the image sensor is disposed on the first die; and
wherein the controller is disposed on the second die.

36. The memory of claim 34, further comprising:
an integrated-circuit die; and
wherein the image sensor and controller are disposed on the die.

37. A photo cell, comprising:
a photo detector; and
a semiconductor region disposed over the photo detector and including germanium.

38. A method, comprising:
forming a first semiconductor region having a first level of germanium;
forming a second semiconductor region having a second level of germanium;
forming a first photo detector in optical alignment with the first region of the layer; and
forming a second photo detector in optical alignment with the second region of the layer.

39. The method of claim 38, further comprising:
forming the first semiconductor region comprises

40. The method of claim 38 wherein:
forming the first semiconductor region comprises growing a first semiconductor layer having the first level of germanium and growing a first thermal insulator over the first region; and
forming the second semiconductor region comprises growing a second semiconductor layer having the second level of germanium and growing a second thermal insulator over the second region.

41. The method of claim 38 wherein forming the first and second semiconductor regions comprises:
growing a first semiconductor layer having the first level of germanium;
growing a second semiconductor layer having the second level of germanium;
forming an optical isolation region between the first and second layers; and
heating the first and second layers to form the first and second semiconductor regions.

42. The method of claim 38 wherein forming the first and second semiconductor regions comprises:
forming a semiconductor layer;
implanting a first region of the semiconductor layer with a first level of germanium to form the first semiconductor region; and
implanting a second region of the semiconductor layer with a second level of germanium to form the second semiconductor region.
